(19) United States
(12) Patent Application Publication
(10) Pub. No.: US 2005/0212524 A1
(43) Pub. Date: Sep. 29, 2005

(54) Electric power line on-line diagnostic method

(76) Inventors: Michael G. Ennis, Evanston, IL (US); Debashis Satpathi, Santa Fe, NM (US)

Correspondence Address: JAMES V. LAPACEK;S & C ELECTRIC CO., 6601 N. RIDGE BLVD., CHICAGO, IL, 60626, US

(21) Appl. No.: 10/999,666

(22) Filed: Nov. 30, 2004

Related U.S. Application Data
(63) Continuation of application No. PCT/US03/18639, filed on Jun. 12, 2003.
(60) Provisional application No. 60/390,310, filed on Jun. 21, 2002.
(60) Provisional application No. 60/390,949, filed on Jun. 24, 2002.

(51) Int. Cl. G01R 31/08

(52) U.S. Cl. 324/521

(57) ABSTRACT

An arrangement and method is provided for determining the present condition and/or expected life of electric power lines via the measurement and analysis of the current into and the current out of the electric power line, thus permitting preventive action on electric power lines before problems arise. In this way, any departure from normal operation may also be detected, e.g. such as caused by a high-impedance fault or the like. The phase angle difference between the input and output currents provides a measure of the condition of the line, i.e. specifically, this phase angle shift between the input and output currents increases as the line ages and loss factors increase. Due to the inherent noise in the current signals, in one embodiment the phase angle shift is measured via a cross-correlation between the input and output current signals to provide the measured phase angle. This phase angle is compared to that of acceptable lines and a determination is then made as to the condition or quality of the measured line. Where the signals are extremely noisy, an auto-correlation process is carried out on one of the current signals to provide an error factor that is a measure of the possible error in the cross-correlation process. This error factor is then subtracted from the phase shift as measured in the correlation process to provide a more realistic estimate of the phase angle shift between the input and output currents.

This application is a continuation of Application No. PCT/US0318639 filed on Jun. 12, 2003 which is a continuation of and claims the benefit of U.S. Provisional Application Nos. 60/390,310 filed Jun. 21, 2002 and 60/390,949 filed Jun. 24, 2002.

### BACKGROUND OF THE INVENTION

1. Field of the Invention

The present invention relates generally to methods and arrangements for determining the present condition and/or expected life of electric power lines via the measurement and analysis of the current into and the current out of the electric power line, thus permitting preventive action on electric power lines before problems arise.

2. Description of Related Art

Various testing and measurement techniques are known for testing the condition of power cables and transmission lines. For example, U.S. Pat. Nos. 6,088,658 and 6,192,317 are directed to the use of statistical techniques including histograms and trend analysis on partial discharge measurements to evaluate the quality of insulation within electrical equipment. An insulated device diagnosing system that also utilizes partial discharge techniques is shown in U.S. Pat. No. 5,982,181 that utilizes measurements at a plurality of specific frequencies. Insulation parameters are calculated in the method and apparatus of U.S. Pat. No. 6,208,149 via voltage measurements at different operating conditions, e.g. different positions of a cable with respect to ground.

While these arrangements may be useful and generally satisfactory for their intended purposes, they do not provide an accurate, on-line measurement of the quality of a power line during normal operating conditions.

### SUMMARY OF THE INVENTION

Accordingly, it is a principal object of the present invention to provide arrangements and methods for determining the present condition and/or expected life of electric power lines via the measurement and analysis of the current into and the current out of the electric power line, thus permitting preventive action on electric power lines before problems arise.

It is another object of the present invention to provide a method for determining departures from normal operation of a power line, e.g. such as those due to high-impedance faults and the like.

These and other objects of the present invention are efficiently achieved by methods and arrangements for determining the present condition and/or expected life of electric power lines via the measurement and analysis of the current into and the current out of the electric power line, thus permitting preventive action on electric power lines before problems arise. In this way, any departure from normal operation may also be detected, e.g. such as caused by a high-impedance fault or the like. The phase angle difference between the input and output currents provides a measure of the condition of the line, i.e. specifically, this phase angle shift between the input and output currents increases as the line ages and loss factors increase. Due to the inherent noise in the current signals, in one embodiment the phase angle shift is measured via a cross-correlation between the input and output current signals to provide the measured phase angle. This phase angle is compared to that of acceptable lines and a determination is then made as to the condition or quality of the measured line. Where the signals are extremely noisy, an auto-correlation process is carried out on one of the current signals to provide an error factor that is a measure of the possible error in the cross-correlation process. This error factor is then subtracted from the phase shift as measured in the correlation process to provide a more realistic estimate of the phase angle shift between the input and output currents.

### BRIEF DESCRIPTION OF THE DRAWING

The invention, both as to its organization and method of operation, together with further objects and advantages thereof, will best be understood by reference to the specification taken in conjunction with the accompanying drawing in which:

FIG. 1 is an electrical circuit representation of an illustrative cable to illustrate methods and arrangements of the present invention;

FIG. 2 is a representation of circuit parameters of the cable of FIG. 1;

FIG. 3 is a phasor representation of parameters of the cable of FIG. 1;

FIG. 4 is a graphical representation of cable parameters of different quality and under different operating conditions; and

FIGS. 5 and 6 are graphical representations of a process used in one embodiment of the present invention to improve the accuracy of measurements.

### DETAILED DESCRIPTION

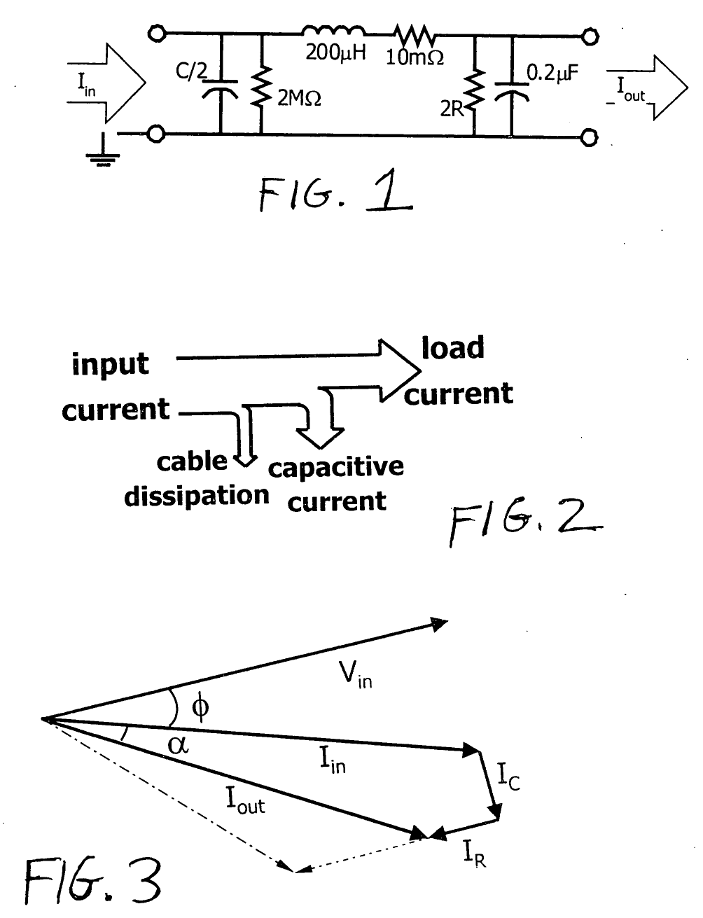

Referring now to FIGS. 1 and 2, the method and arrangement of the present invention are useful to determine the quality of various types of power lines and power cables during normal operating conditions and any departures from normal operating parameters, e.g. both distribution and transmission lines of various types including underground and overhead installations. For illustrative purposes to assist in the description of the present invention, an illustrative power cable may be represented by a pi model or equivalent circuit as shown in FIG. 1 with representative current components being shown as illustrated in FIG. 2. The illustrative values as shown in FIG. 1 are for an EPR (ethylene propylene rubber) cable, but, except for the “R” parameter, the model and values do not change substantially for power cables of other insulation types. As illustrated in FIG. 2, concerning the current Iᵢₙ injected at one terminal, some is lost through the capacitance to the sheath, and of that capacitive current, some is dissipated in the insulation, i.e. “cable dissipation” current. Of course, the majority of the injected current passes out of the other terminal of the cable, i.e. Iₒᵤₜ.

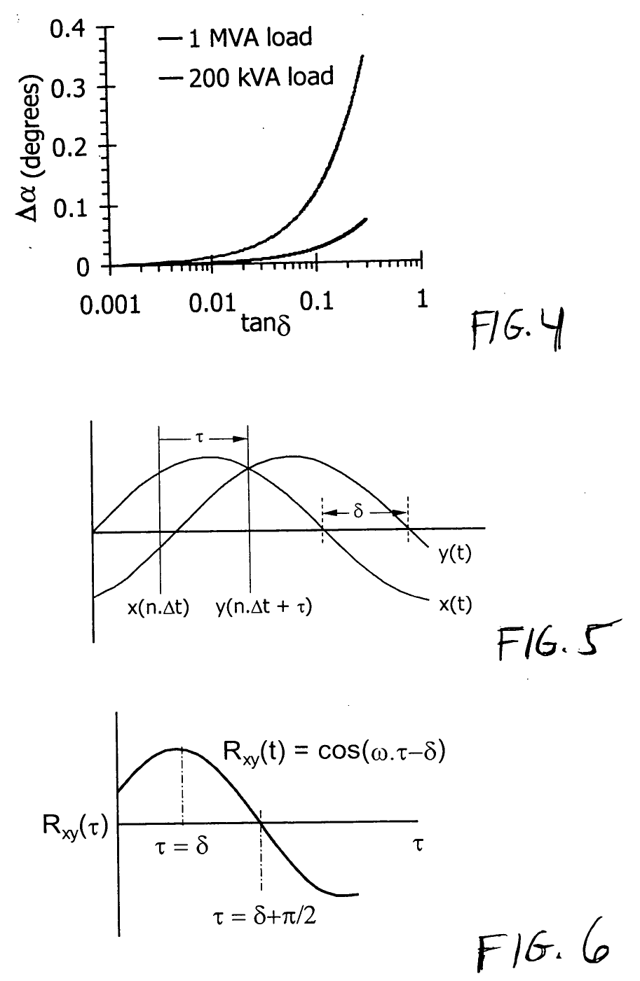

In accordance with important aspects of the present invention, and referring additionally now to FIG. 3, it has been found that as a cable ages and becomes subject to increasing dissipation factors and potential failure, the phase angle shift “α” between the input current and the output current also increases as shown in FIG. 4 represented by the quantity Δα, where tan δ represents the loss factor, a standard measure of the loss factor of a power cable. While the phase angle shift a is small and the change Δα, as the quality of the cable deteriorates is also small, measurement of this change Δα in the angle α between the input current and the output current when compared to that of acceptable cables will provide a determination or indication of the quality of the measured cable. It should be noted that in FIG. 3, some of the phasor quantities are very exaggerated for illustrative purposes. The phasor I_{R} represents the cable dissipation current while the phasor I_{C} represents the current into the capacitance sheath which does not change significantly during aging of a cable. As shown in FIG. 4, the angle α varies with the loss factor as represented by tan δ and the connected load. This factor must also be taken into account for accurate interpretation and determination of the quality of the cable. Additionally, the input and output current signals are typically inherently noisy signals. Thus, additional statistical process steps are generally necessary to obtain accurate results.

For example, in one embodiment of the present invention, and with reference now additionally to FIGS. 5 & 6, a cross-correlation technique of the two waveforms Iᵢₙ and Iₒᵤₜ is utilized, e.g. as given by the general formula shown for two signals x and y:

$${R}_{x y} ( τ ) = \frac{Δ t}{T} {\sum }_{n = 1}^{\frac{T}{Δ t} - 1} x ( n Δ t ) \cdot y ( n Δ t + τ ) \qquad ( 1 )$$

The cross-correlation procedure as illustrated by FIG. 5 is one which can be described as a process of repeatedly trying to align the two waveforms, and detect the shift for which the alignment is “best”. As shown in FIG. 6, the maximum of the alignment function indicates the phase shift between the two signals, i.e. the phase angle shift a that is to be determined. Further, it should also be noted that the output is a sinusoid, even if the two input signals have multiple harmonics, so long as the two waves are periodic.

In accordance with additional aspects of the present invention, even the aforementioned cross-correlation process may be subject to errors due to the noisy nature of the input and output current signals. If so, where it is desirable to further improve the accuracy of the results, in accordance with additional aspects of the present invention, it has been found useful to include additional statistical procedures such as an auto-correlation process to determine the potential error inherent in the cross-correlation process. For example, let a general cross-correlation process be described as follows:

$${X ( x , y )}_{j} = \frac{1}{N} {\sum }_{i = 0}^{N - 1 - j} {x}_{i} \cdot {y}_{i + j} \qquad ( 2 )$$

where x and y are the two vectors, each of length N. The subscript j may be described as the “sweep” of the cross-correlation, and is the number of samples through which the vector y must be stepped in order to locate either a maximum (the conventional case) or a zero of the cross-correlation function. However, note that the larger is j, for a vector of a finite length N, then the smaller will be X(x,y)ⱼ. As we step through the vector y, then, X(x,y)ⱼ will decay. The rate of the decay will be a function of the relative size of j and N, and as the X(x,y)ⱼ decay, the apparent phase angle will change since the resulting function is not symmetric about the x-axis. To perform an auto-correlation procedure, e.g. on one of the input current or output current, the following results:

$${A ( x , x )}_{j} = \frac{1}{N} {\sum }_{i = 0}^{N - 1 - j} {x}_{i} \cdot {x}_{i + j} \qquad ( 3 )$$

For the same reasons that the cross-correlation function decays, so too will the auto-correlation. But we know that there should be no phase difference in the auto-correlation function (because there is no phase difference between the vector x and itself), except that which is due to the finite length of the vector x. Hence the phase angle that results from the auto-correlation is a measure of the “error” we can anticipate from the cross-correlation process. Thus, the potential error determined in the auto-correlation process that may be present in the cross-correlation process is subtracted from the result obtained in the cross-correlation process to provide a more accurate representation of the true phase angle between the two vectors x and y, or in the specific instance, the input current and the output current.

Although the determined phase angle shift a is small and the change in a as a cable ages is still smaller, the arrangement and method of the present invention have been found suitable to provide an on-line determination of power cable quality while the power cable is under normal operating conditions. For example, the angle α may be in the range of 1-5 degrees for a typical cable of a few tenths of a mile in length, while the change Δα in the angle α as the cable deteriorates significantly may only be in the range of 0.1-0.2 degree. In accordance with one specific mode of practice and operation of the present invention, after it has been established that a phase angle shift a for a particular section of a cable installation is “m” degrees, and further that a change Δα in that phase angle shift of “p” degrees from that “m” degrees indicates that the cable quality is no longer satisfactory, a determination is made that the cable is not of good quality and should be replaced. Thus, it is the change in the observed phase angle shift between the input and output currents that provides an indication of undesirable changes in the cable or power line. For example, and considering another embodiment of the present invention, high-impedance faults or other departures from normal operation are detected by the increase Δα in the phase angle shift between the input and output currents such that preventive action may be taken.

While there have been illustrated and described various embodiments of the present invention, it will be apparent that various changes and modifications will occur to those skilled in the art. For example, it should be realized that in specific embodiments, various trending and histogram processes known to those skilled in the art may be combined with the aforementioned description. Accordingly, it is intended in the appended claims to cover all such changes and modifications that fall within the true spirit and scope of the present invention.

1. A method for determining the quality of a power cable comprising the steps of:
determining the phase angle shift between the input current and the output current of the power cable, and
indicating the quality of the power cable based on a comparison of the phase angle shift and a reference value for the power cable.

2. The method of claim 1 wherein the determining step further comprises the step of performing a cross-correlation process between the input current and the output current.

3. The method of claim 2 wherein said determining step further comprises performing an auto-correlation process of either the input current or the output current.

4. The method of claim 1 wherein the indicating step further includes indicating that the quality of the power cable is not good when the phase angle shift exceeds the reference value.

5. The method of claim 1 wherein the reference value in the indicating step is obtained from a prior measurement of the phase angle shift for the power cable.

6. A method for determining changes in the normal operation of a power line comprising the steps of:
determining the phase angle shift between the input current and the output current of the power line, and
indicating a departure from normal operation of the power line based on a predetermined change in the phase angle shift.
